(19) United States
(12) Patent Application Publication
(10) Pub. No.: US 2026/0274595 A1
(43) Pub. Date: Sep. 17, 2026

(54) METHOD FOR OPERATING A LINEAR TRANSPORT SYSTEM AND LINEAR TRANSPORT SYSTEM

(71) Applicant: Beckhoff Automation GmbH, Verl (DE)

(72) Inventors: Manuel Bettenworth, Wien (AT); Marco Grabowski, Bielefeld (DE); Leon Freiberger, Gütersloh (DE); Uwe Prüssmeier, Lemgo (DE); Jan Achterberg, Duisburg (DE); Jannik Berghoff, Gütersloh (DE); Tobias Schönke, Herford (DE)

(21) Appl. No.: 19/673,245

(22) Filed: May 11, 2026

Related U.S. Application Data
(63) Continuation of application No. PCT/EP2025/063437, filed on May 15, 2025.

(30) Foreign Application Priority Data
May 15, 2024 (DE) 10 2024 113 644.8

(51) Int. Cl. B65G 54/02; B65G 43/02; H02K 41/03

(52) U.S. Cl. CPC B65G 54/02; B65G 43/02; H02K 41/031

(57) ABSTRACT

A computer-implemented method for operating a linear transport system comprises outputting control signals to at least one drive coil of a test motor module of a plurality of motor modules, in order to generate a test magnetic field of the test motor module; outputting control signals to at least one drive coil of at least one interference motor module of the plurality of motor modules, in order to generate an interference variable of the at least one interference motor module; determining an interference of the test magnetic field of the test motor module caused by the interference variable of the interference motor module; and determining an interference motor module immediately adjacent to the test motor module, if the detected interference of the test magnetic field by the interference variable reaches or exceeds a predefined limit value. The application also relates to a linear transport system.

### CROSS-REFERENCE TO RELATED APPLICATIONS

This patent application is a continuation of International Patent Application Number PCT/EP2025/063437, filed May 15, 2025, entitled “Method for Operating a Linear Transport System, and Linear Transport System,” which claims the priority of German patent application DE 10 2024 113 644.8, filed May 15, 2024, entitled “Verfahren zum Betreiben eines linearen Transportsystems und lineares Transportsystem,” each of which is hereby incorporated by reference herein, in the entirety and for all purposes.

### FIELD

The application relates to a method for operating a linear transport system. The application also relates to a linear transport system.

### BACKGROUND

Linear transport systems are known from the prior art. Publication DE 10 2012 204 919 A1, for example, describes a linear transport system having a movable unit, a stationary unit with a guide rail for guiding the movable unit, and a linear motor for driving the movable unit along the guide rail, wherein the linear motor comprises a stator and a rotor, wherein the stator comprises a plurality of motor modules arranged in a stationary manner along the guide rail, each of which comprises a plurality of drive coils, wherein the rotor is arranged on the movable unit and comprises a plurality of magnets.

In order to operate the linear transport system, knowledge of the arrangement of individual motor modules of the stationary unit is essential in order to achieve movement of the movable unit along the guide rail by actuating the drive coils of the respective motor modules.

### SUMMARY

The application provides an improved method for operating a linear transport system and an improved linear transport system.

### EXAMPLES

According to an aspect, a computer-implemented method for operating a linear transport system is provided, comprising a controller and a stationary unit having a guide rail for guiding a movable unit and a plurality of motor modules arranged along the guide rail, wherein the motor modules each comprise drive coils for providing a drive magnetic field for driving the movable unit along the guide rail, and wherein the method comprises:

outputting control signals from the controller to at least one drive coil of a motor module selected as a test motor module from the plurality of motor modules to generate a test magnetic field of the motor module selected as the test motor module in a test magnetic field generating step;
outputting control signals by the controller to at least one drive coil of at least one motor module selected as an interference motor module from the plurality of motor modules to generate an interference variable of the at least one motor module selected as an interference motor module in an interference variable generating step;
determining, with the aid of the controller, an interference of the test magnetic field of the motor module selected as the test motor module caused by the interference variable of the motor module selected as the interference motor module in an interference determining step; and
determining a motor module arranged directly adjacent to the motor module selected as the test motor module with the aid of the controller in an arrangement determining step if the determined interference of the test magnetic field caused by the interference variable reaches or exceeds a predefined limit value.

This may achieve the technical advantage of allowing for an improved method for operating a linear transport system. The method allows for determining motor modules immediately adjacent to the motor modules of the stator of the stationary unit. If the position of a motor module within the plurality of motor modules on the stator of the stationary unit is unknown, it is possible to determine whether and, if so, which other motor modules are located immediately adjacent to the selected motor module by actuating the respective motor module and other motor modules of the stator.

For this purpose, at least one motor module is selected from the plurality of motor modules and defined as a test motor module. For the test motor module defined in this way, the motor modules directly adjacent to the test motor module are then determined. This involves the controller of the linear transport system first actuating the previously selected test motor module in order to generate a test magnetic field. The test magnetic field is in this context defined as a magnetic field generated by the test motor module. The test magnetic field may comprise specific predefined properties. However, the test magnetic field is primarily characterized by the fact that it is generated by the test motor module.

Furthermore, at least one additional motor module is selected from the plurality of motor modules of the linear transport system, defined as an interference motor module, and actuated by the controller to generate an interference variable. Analogously to the test motor module, the at least one interference motor module is also a conventional motor module of the stator and is characterized exclusively by the fact that it is actuated to generate the interference variable. The corresponding interference variable is in turn distinguished by the fact that the interference variable is generated by the interference motor module. The interference variable may also have predefined properties.

Subsequently, a check is carried out on whether the interference variable generated by the interference motor module causes an interference in the test magnetic field of the test motor module. If such an interference of the test magnetic field caused by the interference variable of the interference motor module is detected and the detected interference of the test magnetic field reaches or exceeds a predefined limit value, a motor module immediately adjacent to the test motor module is determined.

The described method may thus be used to determine, for a motor module selected as a test motor module from the plurality of motor modules of the stator, which motor module on the stator is immediately adjacent to the motor module selected as the test motor module.

In this context, two motor modules are immediately adjacent to each other within the meaning of the application if no other motor module is arranged between the two motor modules.

The method according to the application is particularly advantageous in situations in which the controller of the linear transport system does not know all the positions of the motor modules within the stator of the stationary unit. Although the controller is capable of controlling the individual motor modules of the stator individually and without error, the actual positions of the motor modules within the stator, i.e. the information on how the individual motor modules are arranged adjacent to one another, is not completely known to the controller.

This situation may occur, for example, when starting up the newly constructed linear transport system. At this point, the individual motor modules are installed on the stationary unit and connected to the controller in terms of data technology. The controller is also able to identify the individual motor modules and actuate them individually. However, the actual positioning of the motor modules on the stationary unit, which depends on the actual assembly of the stationary unit in which the motor modules are installed in at least partially unknown and, as the case may be, arbitrary order within the stator of the stationary unit, is unknown to the controller. A similar case may occur when individual parts of the stationary unit of the existing linear transport system are replaced or modified. The replaced or newly added motor modules are known to the controller at the software level, so that individual addressing or actuating the motor modules by the controller is possible without any problems. However, the actual positioning of the individual motor modules on the stationary unit remains unknown to the controller.

The present method thus allows the controller to automatically determine immediately adjacent motor modules for any selectable motor modules of the stator by actuating the various motor modules and by generating test magnetic fields and interference variables as described above.

By continuing the method for the majority of motor modules the positioning of which is unknown to the controller at the time of executing the method, the topology of the stator, i.e. the positioning of all motor modules on the stator, may be determined or updated.

Manual programming of the existing topology, i.e. the information regarding the positions of the individual motor modules within the stator, into the controller may thus be avoided.

In the sense of the application, an interference variable is a variable that may be generated by switching the motor mode selected as the interference motor module, on the basis of which an interference of the test magnetic field may be generated and detected.

According to an embodiment, the arrangement determining step comprises:
identifying the at least one interference motor module as the motor module arranged immediately adjacent to the test motor module based on a temporal sequence of the generation of the interference variable by the at least one motor module and the determination of the interference of the test magnetic field by the controller in an identifying step.

This may achieve the technical advantage of allowing for further providing the determination of the positions of the motor modules within the stator. This allows the motor module immediately adjacent to the selected test motor module, which was previously determined, to be identified as the motor module selected as the interference motor module. This identification of the motor module immediately adjacent to the test motor module may be achieved, for example, by the fact that at the time of detection of the interference of the test magnetic field of the test motor module caused by the interference variable of the interference motor module, only one interference motor module was actuated by the controller to generate the interference variable. This single energized interference motor module is then identified as the motor module immediately adjacent to the test motor module.

The present method is based on the idea that an interference caused by an interference variable in a test magnetic field is primarily detected or primarily reaches or exceeds the predefined limit value if the respective interference motor module generating the interference variable is located immediately adjacent to the test motor module generating the test magnetic field. Accordingly, if the interference motor module is further away from the test motor module, if, for example, a further motor module is arranged between the interference motor module and the test motor module, the effect of the interference variable generated by the interference motor module on the test magnetic field generated by the test motor module is so small that either no interference in the test magnetic field is detectable or the detected interference does not reach the predefined limit value.

If, when the test motor module is actuated and a corresponding test magnetic field is generated, an interference of the test magnetic field based on an interference variable is detected and the detected interference reaches or exceeds the predefined limit value, it may be concluded according to the application that a motor module immediately adjacent to the motor module selected as the test motor module is positioned. If, furthermore, the detected interference of the test magnetic field may be clearly assigned to an interference variable of an interference motor module, the motor module immediately adjacent to the test motor module may be identified as the interference motor module that generated the interference variable that caused the interference of the test magnetic field.

If a plurality of interference motor modules is actuated simultaneously, thereby generating a plurality of interference variables, then, upon detecting an interference in the test magnetic field of a motor module selected as the test motor module, it may only be determined that a motor module immediately adjacent to the test motor module exists. This immediately adjacent motor module must then be one of the plurality of interference motor modules. However, if the positions of the interference motor modules are not known, it cannot be clearly determined which of the plurality of actuated interference motor modules is located immediately adjacent to the test motor module.

However, if the multiple interference motor modules are actuated sequentially to generate the interference variables, then, upon detecting an interference in the test magnetic field, the interference motor module that was actuated to generate an interference variable at the time the interference in the test magnetic field was detected may be identified as the motor module immediately adjacent to the test motor module.

By identifying the detected motor modules immediately adjacent to one or a plurality of selected test motor modules, complete information about the topology of the linear transport system may be obtained.

According to an embodiment, the interference detecting step comprises:
determining a voltage change in an operating voltage of the drive coil of the test motor module generating the test magnetic field with the aid of the controller in a voltage change determining step, wherein the predefined limit value is defined by the voltage change.

This may achieve the technical advantage that, by measuring the voltage change in the voltage dropping across the drive coil of the test motor module actuated to generate the test magnetic field, precise detection of the interference in the test magnetic field of the test motor module may be achieved. The magnitude of the voltage change may also be used to determine exactly whether the detected interference of the test magnetic field reaches or exceeds the predetermined limit value. In this context, the predefined limit value is defined by a predefined value of the minimum voltage change.

According to an embodiment, the voltage change comprises a change in voltage amplitude and/or a change in voltage phase.

This may achieve the technical advantage that, by taking into account the voltage amplitude or voltage phase of the voltage drop across the drive coil of the test motor module, the voltage change may be precisely determined and, as a result, the interference of the test magnetic field may be precisely detected.

According to an embodiment, the test magnetic field generating step comprises:
outputting control signals via the controller to the drive coil of the test motor module for energizing the drive coil of the test motor module with a first operating current in a first energizing step.

This may achieve the technical advantage of precisely generating the test magnetic field with the aid of the correspondingly actuated drive coil of the test motor module.

According to an embodiment, the interference generating step comprises:
outputting control signals with the aid of the controller to the drive coil of the at least one interference motor module in order to supply the drive coil of the at least one interference motor module with a second operating current and to generate an interference magnetic field in a second energizing step, wherein the interference variable is given by the interference magnetic field.

This may achieve the technical advantage that the interference variable, which is given by the interference magnetic field, may be precisely generated by correspondingly actuating the respective drive coil of the interference motor module accordingly. In the aforementioned embodiment, the interference variable is given by an interference magnetic field that is generated by actively energizing at least one drive coil of the motor module selected as the interference motor module.

The respective drive coil of the interference motor module is in this context actively supplied with an operating current that is set up to generate the desired interference magnetic field. The operating current may be predefined in order to ensure that the generated magnetic field comprises the desired properties.

The interference with the test magnetic field detectable in the motor module selected as the test motor module is based on an interaction between the test magnetic field of the motor module selected as the test motor module and the interference magnetic field of the motor module selected as the interference motor module.

According to an embodiment, the interference generating step comprises:
outputting control signals with the aid of the controller to the drive coil of the at least one interference motor module for generating the interference variable by switching the drive coil of the at least one interference motor module into a short-circuit state in a switching step, wherein the interference variable is given by a short circuit in the drive coil of the motor module selected as the interference motor module.

This may achieve the technical advantage of allowing for a further alternative for generating the interference variable with the aid of the interference motor module. In the embodiment presented, the interference variable is provided by a short circuit in the at least one drive coil of the motor module selected as the interference motor module. In order to generate the interference variable, the respective drive coil of the motor module selected as the interference motor module is not actively supplied with operating current. Instead, the respective drive coil is switched to a short-circuit state. When the correspondingly short-circuited drive coil of the interference motor module interacts with the test magnetic field of the test motor module, a corresponding voltage or current is induced in the short-circuited drive coil of the interference motor module.

The current or voltage induced in at least one drive coil of the interference motor module generates a corresponding interference magnetic field. However, in this embodiment, the interference variable is primarily determined by the short-circuit state that is generated. The interference detectable in the motor module selected as the test motor module and generated by the interference variable is based both on the interference magnetic field generated by induction in the drive coil of the interference motor module and on the interaction between the test magnetic field and the interference magnetic field. Active energizing of the drive coil to generate the interference magnetic field is not required.

According to an embodiment, the first operating current of the drive coil of the test motor module comprises a waveform from the following list: sinusoidal waveform, cosine waveform, sawtooth waveform, triangular waveform, rectangular waveform.

This may achieve the technical advantage that, by energizing the drive coil of the test motor module with the cosine-shaped, sine-shaped, sawtooth-shaped, triangular, rectangular first operating current, a correspondingly cosine or sine wave, sawtooth wave, triangle wave, or rectangular wave operating voltage is generated at the respective drive coil. The corresponding cosine or sine waveform, sawtooth waveform, triangular waveform, or rectangular waveform of the operating voltage dropping at the drive coil of the test motor module facilitates the detection of the change in the operating voltage and, associated with this, the detection of an interference in the test magnetic field. Other current waveforms are also conceivable.

According to an embodiment, the second operating current of the drive coil of the at least one interference motor module comprises a waveform from the following list: sinusoidal waveform, cosine waveform, sawtooth waveform, triangular waveform, rectangular waveform, zero current.

This may achieve the technical advantage of allowing for a precise actuation of the interference motor module to generate the interference variable.

According to an embodiment, a plurality of interference variables is generated for a plurality of interference motor modules by actuating the respective drive coils of the interference motor modules, wherein the plurality of interference variables is checked to determine whether interferences of the test magnetic field of the test motor module are detected.

This may achieve the technical advantage that, by selecting a plurality of motor modules as interference motor modules and by generating a plurality of interference variables for a selected test motor module, it is possible to determine exactly whether a motor module immediately adjacent to the respective test motor module is provided. This makes it possible to achieve a complete topology of the stator or the linear drive system.

According to an embodiment, the generation of the plurality of interference variables of the plurality of interference motor modules is carried out sequentially in time.

This may achieve the technical advantage that, by generating the multiple interference variables sequentially, upon detection of an interference in the test magnetic field of the test motor module, the interference motor module may be clearly identified as the motor module immediately adjacent to the test motor module that was actuated to generate the interference at the time the interference in the test magnetic field was detected. For the test motor module, it may thus be clearly determined which motor modules are positioned immediately adjacent to the test motor module.

According to an embodiment, a plurality of test magnetic fields is generated for a plurality of motor modules selected as test motor modules by actuating the respective drive coils of the motor modules selected as test motor modules.

This may achieve the technical advantage that the respective immediately adjacent motor modules may be determined for each motor module of the plurality of motor modules of the stator. By successively selecting each motor module of the plurality of motor modules as a test motor module for generating the test magnetic field and carrying out the above method, a complete determination of the positioning of all motor modules in the stator may be achieved.

According to an embodiment, the generation of the plurality of test magnetic fields of the plurality of motor modules selected as test motor modules is carried out simultaneously, and the generation of the plurality of interference variables of the plurality of motor modules selected as interference motor modules is carried out sequentially, or the generation of the plurality of test magnetic fields of the plurality of motor modules selected as test motor modules is carried out sequentially in time and the generation of the plurality of interference variables of the plurality of motor modules selected as interference motor modules is carried out simultaneously.

This may achieve the technical advantage that the motor modules immediately adjacent to a plurality of motor modules may be determined. By generating the test magnetic fields and/or interference variables simultaneously, the determination of the motor modules immediately adjacent to the plurality of motor modules selected as test motor modules may be carried out as quickly as possible.

According to an embodiment, the method further comprises:
determining that no immediately adjacent motor module exists for the test motor module if no interference of the test magnetic field is determined for any of the generated interference variables of the motor modules selected as interference motor modules, in a further arrangement determining step.

This may achieve the technical advantage that gaps between the motor modules and/or ends or beginnings of the travel distances of the stationary unit defined by the plurality of motor modules of the stationary unit may be determined. Motor modules selected as test motor modules for which no immediately adjacent motor module is detected in a direction are interpreted as the end/beginning of the travel distance in the respective direction.

According to an embodiment, the motor modules of the plurality of motor modules of the stationary unit are grouped into motor module strings, each motor module string comprising at least two motor modules connected to one another by wires, and the method comprises:
determining a test edge motor module of a test motor module string and an interference edge motor module of an interference motor module string with the aid of the controller in a motor module determining step, wherein the test edge motor module is connected by wire to only one other motor module of the test motor module string, and wherein the interference edge motor module is connected by wire to only one other motor module of the interference motor module string; and
selecting the test edge motor module of the test motor module string as the test motor module for generating the test magnetic field and selecting the interference edge motor module of the interference motor module string as the interference motor module for generating the interference variable by the controller in a motor module selecting step.

This may achieve the technical advantage that, when combining motor modules into motor module strings, an immediately adjacent motor module string may be determined for each motor module string by implementing the method according to the application. In a motor module string, the at least two motor modules of the respective motor module string are connected to one another via cables. The positions of the motor modules within the motor module string are known via the wired connection of the controller. However, the controller does not know the positions at which the individual motor module strings are formed in the stator, nor does it know the positions of the adjacent motor module strings.

Each motor module string comprises at least two edge motor modules. In order to determine the motor module strings immediately adjacent to a selected motor module string, at least one of the at least two edge motor modules is selected as a test edge motor module for generating one or two test magnetic fields. Furthermore, the edge motor modules of the other motor module strings are selected as interference edge motor modules for generating corresponding interference variables.

Based on this, the method is carried out in accordance with the method steps described above and interferences of the respective test magnetic fields caused by the interference variables of the interference edge motor modules of the further motor module strings are determined for the at least one or the two test edge motor modules. This allows for determining the motor module strings immediately adjacent to a motor module string selected as a test motor module string.

Since the positions of the motor modules within a motor module string are known, only the edge motor modules of the respective motor module strings are selected as test motor modules or interference motor modules. Only these may be positioned immediately adjacent to motor modules of an immediately adjacent further motor module string.

According to an embodiment, the method further comprises:
determining a topology of the motor modules of the stationary unit by determining at least one immediately adjacent motor module for each motor module of the plurality of motor modules of the stationary unit by the controller in a topology determining step.

This may achieve the technical advantage that a complete topology of the linear transport system may be determined by carrying out the method described above.

According to an embodiment, the linear transport system comprises a signal transmitting device formed on a movable unit, wherein the method comprises:
outputting control signals with the aid of the controller to actuate coils of the motor modules for actuating the drive coils to position the movable unit in a transmission position of the movable unit relative to the stationary unit in a positioning step, wherein, in the transmission position of the movable unit relative to the stationary unit, the signal transmitting device is positioned with a first transmitting element in an effective range of the interference variable and a second transmitting element in an effective range of the test magnetic field, and wherein a magnetic interference signal of the interference variable is transmitted into the effective range of the test magnetic field by the signal transmitting device.

This may achieve the technical advantage that the method according to the application may also be carried out for motor modules that are far apart with the aid of the signal transmitting device. For this purpose, the signal transmitting device comprises two transmitting elements, each of which may be positioned in the effective ranges of a test magnetic field of a motor module selected as a test motor module and in the effective range of an interference variable of a motor module selected as an interference motor module. The signal transmitting device may be used to introduce the magnetic interference signal generated by the interference variable into the effective range of the test magnetic field of the test motor module in order to cause interference with the test magnetic field. The signal transmitting device may thus bridge distances between motor modules that would otherwise prevent the interference variables generated by the respective motor modules from affecting the test magnetic fields generated by the respective motor modules.

By forming the signal transmitting device on at least one movable unit of the linear transport system, the signal transmitting device may be positioned on any motor modules by moving the movable unit along the guide rail in order to determine the respective immediately adjacent motor modules for the respective motor modules by carrying out the method according to the application.

According to an embodiment, the method is carried out when the linear transport system is started up and/or after a motor module has been added to and/or removed from the plurality of motor modules.

This may achieve the technical advantage that the method according to the application may be carried out at different times during operation of the linear transport system. As already described above, when the linear transport system is started up for the first time, the present method may be used to determine the positions of the various motor modules within the stator, which are unknown to the controller at this point in time. Furthermore, the method according to the application may be used when parts of an existing linear transport system are changed, for example by replacing or modifying motor modules or sections of the linear transport system, and the respective positions of the newly added or rearranged motor modules are therefore still unknown to the controller. The method may thus be used at any time for different sections of the route or for the entire linear transport system.

According to an aspect, a linear transport system is provided with a controller and a stationary unit, wherein the stationary unit comprises a guide rail for guiding a movable unit and a plurality of motor modules arranged along the guide rail, wherein the motor modules each comprise drive coils for providing a drive magnetic field for driving the movable unit along the guide rail, wherein the drive coils are arranged to generate a test magnetic field and/or an interference variable, wherein the controller is arranged to carry out the method for operating a linear transport system according to one of the above-described embodiments.

This may achieve the technical advantage of providing an improved linear transport system that is configured to carry out the method according to the application with the technical advantages described above.

According to an embodiment, the linear transport system further comprises a signal transmitting device, wherein the signal transmitting device is configured to transmit a magnetic interference signal of the interference variable of a drive coil of at least one interference motor module into an effective range of the test magnetic field of a drive coil of a test motor module of the plurality of motor modules.

This may achieve the technical advantage that the signal transmitting device allows for carrying out the method according to the application for motor modules that are spaced apart from one another and for which the correspondingly generated test magnetic fields and interference magnetic fields of the interference variables do not interact due to the distance, which would lead to an interference of the test magnetic field that would reach or exceed the predefined limit value.

According to an embodiment, the signal transmitting device comprises a first transmitting element and a second transmitting element wire-connected to the first transmitting element, wherein the first transmitting element may be positioned in the effective range of the interference variable and the second transmitting element may be positioned in the effective range of the test magnetic field.

This may achieve the technical advantage that the first and second transmitting elements of the signal transmitting device may bridge the distance between two motor modules, which would otherwise prevent the interference variable from affecting the test magnetic field.

According to an embodiment, the signal transmitting device is formed on the stationary unit, wherein the first transmitting element is arranged within the effective range of the interference variable of the at least one interference motor module, and wherein the second transmitting element is arranged within the effective range of the test magnetic field of the drive coil of the test motor module.

This may achieve the technical advantage that the signal transmitting device may introduce the interference signal of the interference variable of the interference motor module into the effective range of the test magnetic field of the test motor module. When the control motor module is actuated and the interference variable is generated, the magnetic interference signal introduced into the effective range of the test magnetic field of the test motor module via the signal transmitting device may be used to detect an interference in the test magnetic field. This may then be used to identify the respective interference motor module as a motor module directly adjacent to the test motor module.

According to an embodiment, the signal transmitting device is arranged on the movable unit of the linear transport system, wherein the first transmitting coil may be positioned in the effective range of the interference variable and the second transmitting coil in the effective range of the test magnetic field with the aid of a process involving the movable unit along the guide rail.

This may achieve the technical advantage that the signal transmitting device may be moved to any motor module with the aid of the movable unit. The signal transmitting device therefore does not have to be installed on the stationary unit for every possible motor module. By moving the movable unit, the signal transmitting device may be transported to the desired motor modules for which it is to be checked which motor modules are positioned in the immediate vicinity. This may substantially reduce the number of signal transmitting devices required in the entire linear transport system.

According to an embodiment, the first transmitting element is embodied as a first transmitting coil and the second transmitting element is embodied as a second transmitting coil, wherein when the first transmitting coil is positioned in the effective range of the interference variable and the second transmitting coil is positioned in the effective range of the test magnetic field, a voltage signal may be induced in the first transmitting coil by the interference variable, wherein a current signal may be generated by the induced voltage signal in the second transmitting coil, and wherein a magnetic interference signal corresponding to the interference variable may be generated by the second transmitting coil energized by the current signal and introduced into the effective range of the test magnetic field.

This may achieve the technical advantage that, by embodying the first and second transmitting elements as corresponding first and second transmitting coils, reliable transmission of the magnetic interference signal generated by the interference variable of the interference motor module into the effective range of the test magnetic field of the test motor module is achieved.

### BRIEF DESCRIPTION OF THE DRAWINGS

The application is described in more detail with reference to the accompanying figures, which show:

FIG. 1 is a top view of a linear transport system according to an embodiment;

FIG. 2 is a side view of two motor modules of the linear transport system according to FIG. 1;

FIG. 3 is a schematic depiction of the linear transport system according to a further embodiment;

FIGS. 4A to 4D are a diagramal depictions of method steps of a method for operating a linear transport system according to a further embodiment;

FIG. 5 is a schematic depiction of the linear transport system according to a further embodiment;

FIG. 6 is a schematic depiction of the linear transport system according to a further embodiment;

FIGS. 7A to 7C are schematic depictions of the linear transport system according to a further embodiment;

FIGS. 8A and 8B are schematic depictions of the linear transport system according to a further embodiment;

FIG. 9 is a flowchart of the method for operating a linear transport system according to an embodiment;

FIG. 10 is a further flowchart of the method for operating a linear transport system according to a further embodiment;

FIG. 11 is a further flowchart of the method for operating a linear transport system according to a further embodiment;

FIG. 12 is a further flowchart of the method for operating a linear transport system according to a further embodiment;

FIG. 13 is a further flowchart of the method for operating a linear transport system according to a further embodiment;

FIG. 14 is a further flowchart of the method for operating a linear transport system according to a further embodiment; and

FIG. 15 is a further flowchart of the method for operating a linear transport system according to a further embodiment.

In the following, the same reference numerals may be used for elements with the same function. Where appropriate, these elements will not be described again in each figure. Nevertheless, these elements with the same function may be provided accordingly in all embodiments.

### DETAILED DESCRIPTION

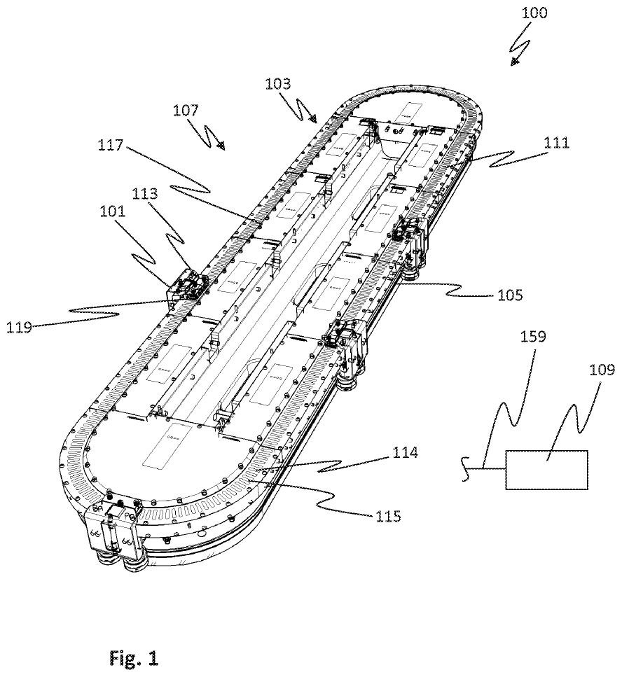

FIG. 1 shows a schematic top view of a linear transport system 100. The linear transport system 100 comprises at least a movable unit 101, a stationary unit 103 having a guide rail 105 for guiding the at least one movable unit 101, and a linear motor 107 for driving the movable unit 101 along the guide rail 105.

The linear motor 107 comprises a stator 111 and at least a rotor 113. The stator 111 is embodied on the stationary unit 103, while the at least one rotor 113 is embodied on the at least one movable unit 101. The stator 111 is arranged adjacent to the guide rail 105 on the stationary unit 103 and comprises a plurality of stator teeth 114 arranged in a stationary manner along the guide rail 105 and drive coils 115. Every second stator tooth 114 is wound by a drive coil 115 and thus serves as a coil core for the respective drive coil 115. The stator teeth 114 may be made of a ferromagnetic material. Energizing of the drive coils 115 may lead to a strengthening of the drive magnetic field through the stator teeth 114.

The at least one rotor 113 embodied at the at least one movable unit 101 comprises a plurality of drive magnet elements 119. A rotor magnetic field may be generated via the drive magnet elements 119 of the rotor 113. Stator magnetic fields may be generated via the energizable drive coils 115, so that a movement of the movable unit 101 along the guide rail 105 may be achieved via a magnetic coupling between the rotor magnetic field of the rotor 113 of the movable unit 101 and the stator magnetic fields of the stator 111, which may be variably generated by energizing the drive coils 115.

The plurality of the drive coils 115 of the stator 111 are combined in a plurality of motor modules 117. The stator 111 thus comprises a plurality of motor modules 117, each of which in turn comprises a plurality of energizable drive coils 115. The motor modules 117 are arranged along the guide rail 105 at the stationary unit 103. The motor modules 117 may be actuated individually by the controller 109.

FIG. 1 also shows that the linear transport system 100 comprises a controller 109 which is connected to one or a plurality of the motor modules 117 with the aid of a data line 159. In particular, communication between the controller 109 and the motor modules 117 may take place via a data bus, for example a field bus, wherein the data bus may be provided via the data lines 159.

In particular, the controller 109 may be an active subscriber and provide the data bus, while the motor modules 117 may be passive subscribers that are addressed by the data bus. As the case may be, it may also be provided that each of the motor modules 117 is connected directly to the controller 109. The data lines 159 may also provide a current and/or voltage supply to the motor modules 117. Alternatively, it is possible to use additional, unshown lines for the current and/or voltage supply.

Alternatively, the controller 109 may also be embodied in one or a plurality of motor modules 117. Data exchange between the controller 109 and the motor modules 117 may also be minimized.

In addition, the lines, in particular the data lines 159 but also other lines, may be connected to the motor modules 117 in a pluggable manner. This may be achieved with the aid of appropriately embodied connectors. This may be used to connect the motor modules 117 to a power supply or the controller 109, as well as to connect the motor modules 117 to each other. For this purpose, the motor modules 117 may each comprise, for example, two connection elements with an input element and an output element. The connection elements may be arranged, for example, at the edge areas of the motor modules 117.

The controller 109 may be set up to issue control commands to the motor modules 117 in order to control the motor modules 117 to energize the drive coils 115 and thereby cause the movable units 101 to move along the guide rail 105.

In order to operate the linear transport system 100, it is essential that the positioning of each motor module 117 on the stationary unit 103 of the controller 109 is known to the controller 109. Only in this way may the controller 109 actuate the correct motor modules 117 or the respective drive coils 115 to allow for moving the movable units 101 along the guide rail 105.

When the linear transport system is started up or after a modification of the linear operating system 100 in which additional motor modules 117 have been added to the existing motor modules 117 of the stator 111, or in which existing motor modules 117 of the stator 111 have been replaced or removed, the controller 109 may not be aware of every position of every motor module 117 on the stator 111 of the stationary unit 103.

Similarly, it may be the case that during assembly, the data lines and associated slots for the data lines on the controller are unclear or have been mixed up.

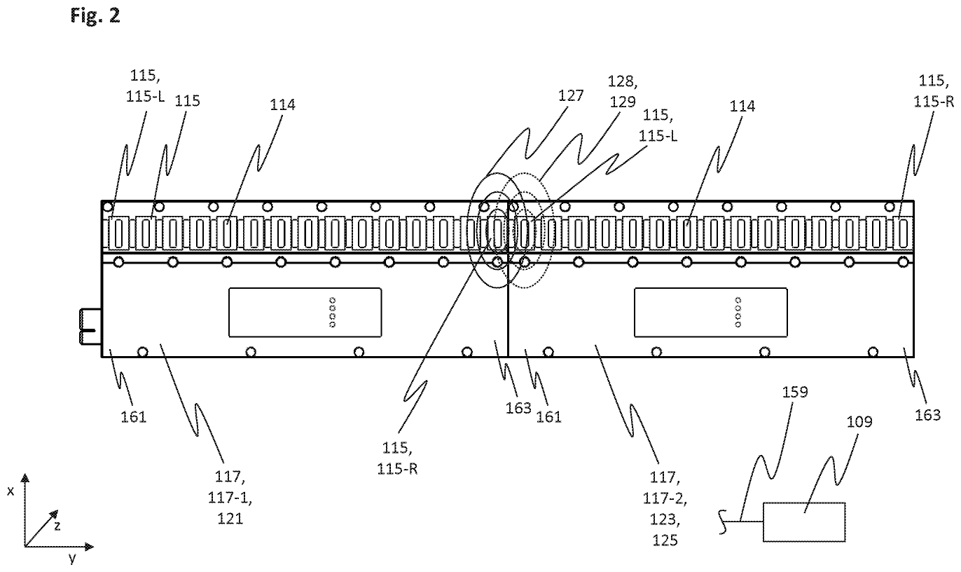

FIG. 2 shows a further schematic depiction of the linear transport system 100 from FIG. 1. FIG. 2 shows only a section, in particular only two immediately adjacent motor modules 117, of the stationary unit 103 of the linear transport system 100.

In order to determine the positions of the motor modules 117 on the stator 111, i.e. the topology of the stator 111 of the movable unit 103, the controller 109 is configured according to the application to carry out the method according to the application for operating a linear transport system 100. When carrying out the method for operating a linear transport system, the controller 109 determines for each motor module 117 of the plurality of motor modules 117 of the stator 111 whether an immediately adjacent motor module 125 is arranged on the stator 111 for the respective motor module 117.

For this purpose, a motor module 117 is selected from the plurality of motor modules 117 as a test motor module 121. FIG. 2 shows a first motor module 117-1 and a second motor module 117-2 of the stator 111. Purely by way of example, the first motor module 117-1 is selected as the test motor module 121 in order to explain the method according to the application.

The test motor module 121 is any motor module 117 of the plurality of motor modules 117 of the stator 111. For the purposes of the application, the test motor module 121 is the motor module 117 of the plurality of motor modules 117 of the stator 111 for which it is determined by carrying out the method whether a motor module 125 is provided immediately adjacent to the selected test motor module 121.

For this purpose, the test motor module 121 is actuated by the controller 109 to generate a test magnetic field 127 through at least one of the drive coils 115 of the test motor module 121. The test magnetic field 127 is a magnetic field generated by the motor module 117 selected as the test motor module 121.

In the embodiment shown, the motor modules 117 comprise have a plurality of drive coils 115 which are arranged at a distance from one another along the longitudinal axis LA of the respective motor module 117. The motor modules 117-1, 117-2 each have a first edge drive coil 115-L at a first end 161 and a second edge drive coil 115-R at a second end 163 opposite the first end 161.

In the example shown, the test magnetic field 127 is generated by correspondingly actuating the second edge drive coil 115-R arranged at the second end 163 of the first motor module 117-1 selected as the test motor module 121. The effective range of the test magnetic field 127 generated by the second edge drive coil 115-R is primarily arranged around the second end 163 of the first motor module 117-2.

The effective range of the test magnetic field 127 is defined as a spatial area arranged around the drive coil 115, which generates the test magnetic field 127, in which the test magnetic field 127 may interact with other magnetic fields or with a magnetizable and/or electrically conductive component.

As an alternative or in addition, the first edge drive coil 115-L arranged at the first end of the first motor module 117-1 may also be actuated to generate the test magnetic field 127.

In order to determine whether a further motor module 117 is located immediately adjacent to the test motor module 121, at least one further motor module 117 of the stator 111 of the stationary unit 103 is selected and actuated as an interference motor module 123 to generate an interference variable 128.

In the following, the interference variable 128 in the form of an interference magnetic field 129 is taken into account in the explanation of the method according to the application. The output of control signals via the controller 109 to generate the interference variable 128 may include both actively energizing a drive coil 115 of the motor module 117 selected as the interference motor module 123 to generate the respective interference magnetic field 129 and generating an interference variable 128 in the form of a short circuit 132 of a drive coil 115 of the motor module 117 selected as the interference motor module 123, wherein even in the case of the interference variable 128 in the form of a short circuit 132, an interference magnetic field 129 is generated passively.

In the example shown, the second motor module 117-2 is selected as the interference motor module 123 and is actuated accordingly to generate an interference variable 128, e.g. in the form of an interference magnetic field 129. The interference magnetic field 129 is the magnetic field generated by the motor module 117 selected as the interference motor module 123.

For better and simpler depiction, only the field components arranged in the image plane are shown in the figures for the test magnetic fields 127 and the interference magnetic fields 129. However, the test magnetic fields 127 and interference magnetic fields 129 may also comprise field components that are oriented perpendicularly with regard to the image plane. These field components oriented perpendicularly with regard to the image plane may be stronger than the field components shown and running in parallel with regard to the image plane.

Similar to the test motor module 121, the interference motor module 123 is a conventional motor module 117 of the stator 111 and is characterized in that it is actuated to generate the interference magnetic field 129. The interference magnetic field 129 is in turn a magnetic field generated by at least one drive coil 115 of the motor module 117 selected as the interference motor module 123.

In the example shown, the interference magnetic field 129 is generated by energizing the first edge drive coil 115-L arranged at the first end 161 of the second motor module 117-2. An effective range of the interference magnetic field 129 is primarily located in the area of the first end 161 of the second motor module 117-2.

By convention, it may e.g. be specified that the test magnetic fields 127 of the motor modules 117 selected as test motor modules 121 are always generated by energizing the second edge drive coils 115-R arranged at the second ends 163 of the respective motor modules 117, and that the interference magnetic fields 129 of the motor modules 117 selected as interference motor modules 123 are always generated by energizing the first edge drive coils 115-L arranged at the first ends 161 of the respective motor modules 117.

As an alternative or in addition, the test magnetic fields 127 may always be generated by energizing the first edge drive coils 115-L and the interference magnetic fields 129 may always be generated by energizing the second edge drive coils 115-R of the motor modules 117 selected as test motor modules 121 or interference motor modules 123, respectively.

If interference magnetic fields 129 are generated by more than one interference motor module 123, this plurality of interference magnetic fields 129 may be generated simultaneously or sequentially.

In order to determine whether a motor module 125 is immediately adjacent to the first motor module 117-1 selected as the test motor module 121, a check is now carried out to determine whether an interference caused by the interference magnetic field 129 of the interference motor module 123, i.e. the second motor module 117-2, is detected in the test magnetic field 127 of the test motor module 121, i.e. the first motor module 117-1.

If the test motor module 121 and the at least one interference motor module 123 are arranged immediately adjacent to each other, i.e. if no other motor module 117 is arranged between the test motor module 121 and the interference motor module 123, an interaction between the test magnetic field 127 and the at least one interference magnetic field 129 may be achieved. This interaction may be registered at least in the test motor module 121 in the form of an interference of the test magnetic field 127.

If such an interference of the test magnetic field 127 caused by the interference magnetic field 129 of at least one interference motor module 123 is registered and the registered interference of the test magnetic field 127 reaches or exceeds a predefined limit value, a motor module 125 immediately adjacent to the test motor module 121 is determined.

In the example shown, an interaction exists between the test magnetic field 127 of the first motor module 117 selected as the test motor module 121-1 selected as the test motor module 121 and the interference magnetic field 129 of the second motor module 117-2 selected as the interference motor module 123, and the interaction detects an interference in the test magnetic field 127 of the test motor module 121 that reaches or exceeds the predefined limit value.

Based on the interference of the test magnetic field 127 generated by the interference magnetic field 129 of the second motor module 117-2, the controller 109 determines that a further motor module 117 is located immediately adjacent to the second end 163 of the first motor module 117-1.

If, in the example shown, the first motor module 117-1 selected as the test motor module 121 and the second motor module 117-2 selected as the interference motor module 123 were further apart from each other, for example by arranging a further motor module 117 between the first motor module 117-1 and the second motor module 117-2, the test magnetic field 127 of the first motor module 117-1 and the interference magnetic field 129 of the second motor module 117-2 would not interact with each other, and no interference would be generated or detected in the test magnetic field 127 of the first motor module 117-1 by the interference magnetic field 129 of the second motor module 117-2.

Based on the fact that, after energizing the first edge drive coil 115-L of the second motor module 117-2, no interference with the test magnetic field of the first motor module 117-1 would be detected in the first motor module 117-1, it may be determined that the second motor module 117-2 is not located immediately adjacent to the second end 163 of the first motor module 117-1.

If the test magnetic field 127 is generated by the first edge drive coil 115-L of the first motor module 117-1 selected as the test motor module 121, then, if an interference of the test magnetic field 127 is detected by an interference magnetic field 129 of a motor module 117 other than the second motor module 117-2 shown here, a further motor module 125 immediately adjacent to the first motor module 117-1 may be detected based on the detected interference of the test magnetic field 127, wherein this further immediately adjacent motor module would be arranged adjacent to the first end 161 of the first motor module 117-1.

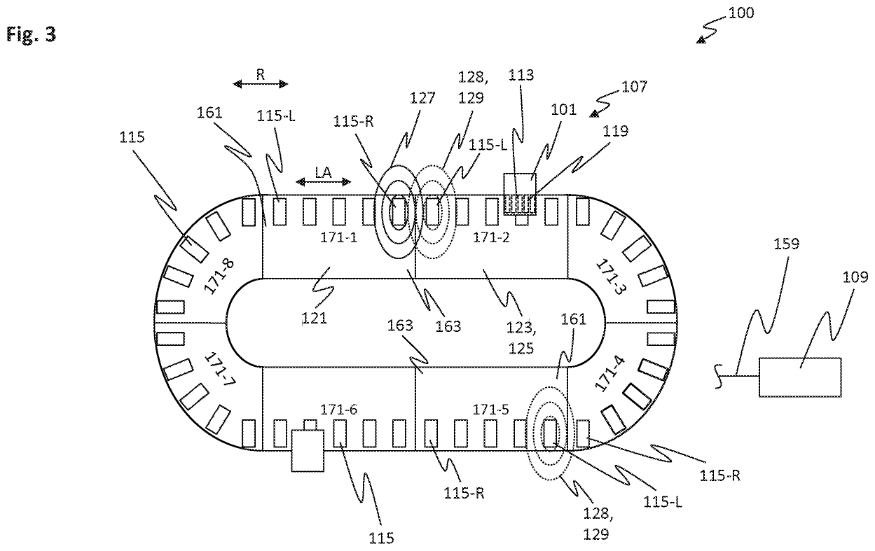

FIG. 3 shows a further schematic depiction of the linear transport system 100 from FIG. 1. FIG. 3 shows a plurality of motor modules 117 of the stator 111 of the stationary unit 103. Eight motor modules 117-1, . . . , 117-8 are shown in a circular circuit.

In order to illustrate further steps of the method according to the application, the first motor module 117-1 is again selected as the test motor module 121. Analogously to FIG. 2, the second edge drive coil 115-R of the first motor module 117-1 is again energized to generate the test magnetic field 127.

In order to determine whether and which motor modules 117 are adjacent to the first motor module 117-1 selected as the test motor module 121, a plurality of motor modules 117 are now selected as interference motor modules 123 for generating interference magnetic fields 129. In the example shown, the second motor module 117-2 and the fifth motor module 117-5 are selected as interference motor modules 123.

At the time of carrying out the method, the order of the motor modules 117 along the stationary unit 103 of the controller 109 is at least partially unknown. Any motor modules 117 of the stationary unit 103 are selected as both test motor modules 121 and interference motor modules 123.

Following the convention of the embodiment in FIG. 2, in the embodiment shown the first edge drive coils 115-L of the second and fifth motor modules 117-2, 117-5 selected as interference motor modules 123 are each energized to generate the interference magnetic fields 129.

Analogously to the embodiment in FIG. 2, in FIG. 3 the second motor module 117-2 is arranged directly at the second end 163 of the first motor module 117-1 selected as the test motor module 121. The test magnetic field 127 of the first motor module 117-1 is thus disturbed by interaction with the interference magnetic field 129 of the second motor module 117-2. Due to the interference with the test magnetic field 127, the second motor module 117-2 is thus determined according to the application to be the motor module 125 immediately adjacent to the first motor module 117-1. Since only the second edge drive coil 115-R is energized in the first motor module 117-1 to generate the test magnetic field 127, the determined interference of the test magnetic field 127 by the interference magnetic field 129 of the second motor module 117-2 allows the second motor module 117-2 to be determined as being located immediately adjacent to the second end 163 of the first motor module 117-1.

Since the fifth motor module 117-5 is not located immediately adjacent to the first motor module 117-1, no interaction between the interference magnetic field 129 of the fifth motor module 117-5 and the test magnetic field 127 of the first motor module 117-1 may be achieved. The interference magnetic field 129 of the fifth motor module 117-5 therefore does not interfere with the test magnetic field 127 of the first motor module 117-1.

If the first two edge drive coils 115-L of the second motor module 117-2 and the fifth motor module 117-5 are energized simultaneously to generate the interference magnetic fields 129, determining the interference with the test magnetic field 127 of the first motor module 117-1 only reveals that a directly adjacent motor module 125 is located at the second end 163 of the first motor module 117-1. However, it cannot be determined whether this immediately adjacent motor module 125 is the second motor module 117-2 or the fifth motor module 117-5.

If, on the other hand, the first two edge drive coils 115-L of the second motor module 117-2 and the fifth motor module 117-5 are energized one after the other and the two interference magnetic fields 129 are thus also generated one after the other and without temporal overlap, then, based on the determined interference of the test magnetic field 127, the second motor module 117-2 may be identified as the motor module 125 immediately adjacent to the second end 163 of the first motor module 117-1.

Since the interference magnetic field 129 of the fifth motor module 117-5 does not generate any interference in the test magnetic field 127 of the first motor module 117-1, in the configuration shown, the generation of the interference magnetic field 129 by the fifth motor module 117-5 may only be used to determine that the fifth motor module 117-5 is not located directly adjacent to the second end 163 of the first motor module 117-1. However, it cannot be determined at which point the fifth motor module 117-5 is arranged on the stator 111 of the stationary unit 103.

As an alternative to the two motor modules 117, which in the example shown generate the interference magnetic fields 129 as interference motor modules 123, a larger number of motor modules 117 may also be controlled to generate interference magnetic fields 129. If the multiple motor modules 117 are controlled in succession, in particular in a time sequence, to generate the interference magnetic fields 129, the actuation may be interrupted as soon as an interference of the test magnetic field 127 of the motor module 117 selected as the test motor module 121 is detected.

In order to determine the motor module 125 immediately adjacent to the first end 161 of the first motor module 117-1 selected as the test motor module 121, the first edge drive coil 115-L may be energized to generate the test magnetic field 127 and the above-described procedure may be continued.

In order to determine the complete topology, the above method may be continued in such a way that each of the motor modules 117 of the stator 111 of the stationary unit 103 is selected in succession as the test motor module 121 for generating the test magnetic field 127, wherein the respective other motor modules 117 generate the interference magnetic fields 129 as interference motor modules 123.

Alternatively, all motor modules 117 of the stator 111 of the stationary unit 103 may be selected as test motor modules 121 and the second edge drive coils 115-R of the selected motor modules 117 may be energized to generate the test magnetic fields 127. Furthermore, the first edge drive coils 115-L in all motor modules 117 of the stator 111 of the stationary unit 103 may be energized to generate the interference magnetic fields 129.

The motor modules 117 thus serve as test motor modules 121 with their second edge drive coils 115-R, which generate the test magnetic fields 127, and at the same time as interference motor modules 123 with their first edge drive coils 115-L, which generate the interference magnetic fields 129.

In this context, either all second edge drive coils 115-R of the motor modules 117 may be energized simultaneously to generate the test magnetic fields 127, and the first edge drive coils 115-L of the motor modules 117 may be energized sequentially and individually to generate the interference magnetic fields.

Alternatively, the second edge drive coils 115-R of the motor modules 117 may be energized sequentially and individually to generate the test magnetic fields 127, and the first edge drive coils 115-L of the motor modules 117 of the stator 111 may be energized simultaneously to generate the interference magnetic fields 129.

The test magnetic fields 127 are generated sequentially in such a way that no temporal overlap occurs between two test magnetic fields 127. Similarly, the interference magnetic fields 129 are generated sequentially in such a way that there is no temporal overlap between two interference magnetic fields 129.

By generating the test magnetic fields 127 in all motor modules 117 via the second edge drive coils 115-R and the interference magnetic fields 129 via the first edge drive coils 115-L, a motor module 125 immediately adjacent to the second end 163 may be determined for each motor module 117 if such a motor module 117 is arranged in the stator 111. By carrying this out for all motor modules 117, the complete topology of the stator 111 of the static unit 103 may be determined.

If, on the other hand, no interference of the test magnetic field 127 by a disturbing magnetic field 129 of at least one of the other motor modules 117 is detected for a motor module 117 selected as a test motor module 121, it is recognized that no immediately adjacent motor module 125 is arranged at the second end 163 of the respective motor module 117.

Alternatively, the first edge drive coils 115-L may be energized to generate the test magnetic fields 127 and the second edge drive coils 115-R of the motor modules 117 may be energized to generate the interference magnetic fields 129. The method is carried out analogously in this case.

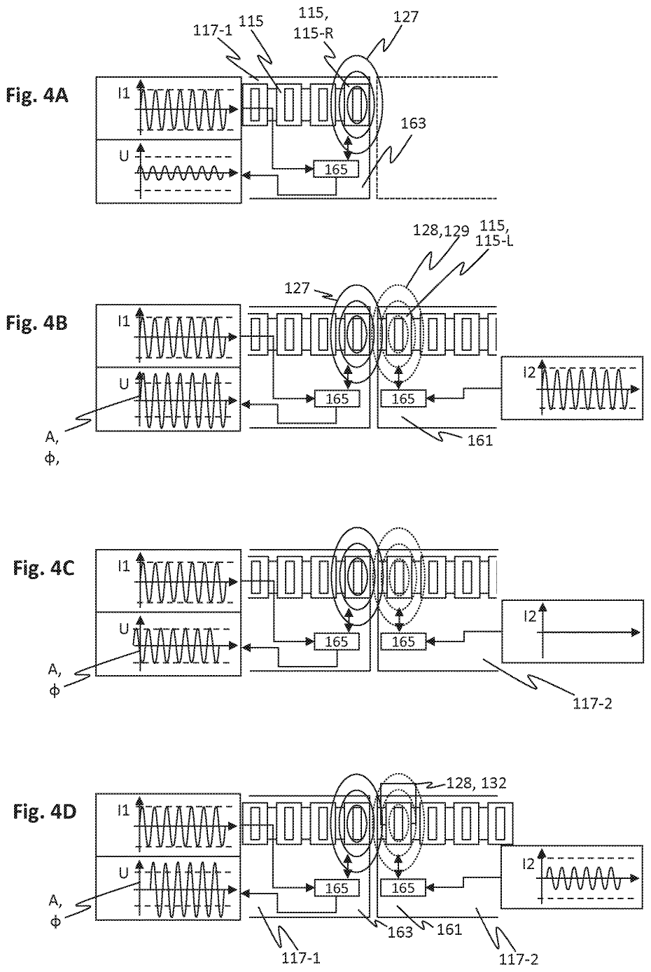

FIGS. 4A to 4D show diagramal depictions of the steps of a method for operating a linear transport system 100. The diagrams of FIGS. 4A to 4D diagramally represent various steps or embodiments of the method described above for operating a linear transport system 100. For this purpose, a first motor module 117-1 and a second motor module 117-2 are shown in the diagrams of FIGS. 4B to 4D. The first motor module 117-1 and the second motor module 117-2 are only partially shown. A plurality of drive coils 115 are shown for both motor modules 117-1 and 117-2. In particular, the second edge drive coil 115-R arranged at the second end 163 of the first motor module 117-1 and the first edge drive coil 115-L arranged at the first end 161 of the second motor module 117-2 are shown.

Analogously to the method described in FIGS. 1 to 3, the first motor module 117-1 is now selected as a test motor module 121 and the second motor module 117-2 is selected as an interference motor module 123. In order to determine the motor modules 117 arranged immediately adjacent to the first motor module 117-1 selected as the test motor module 121, the second edge drive coil 115-R of the first motor module 117-1, which is located adjacent to the second end 163, is now actuated to generate the test magnetic field 127. Accordingly, in the diagrams of FIGS. 4B to 4D, the first edge drive coil 115-L of the second motor module 117-2 selected as the interference motor module 123, which is positioned adjacent to the first end 161 of the second motor module 117-2, is actuated to generate the interference variable 128.

In the embodiments shown in the diagrams of FIGS. 4A to 4D, the second drive coil 115-R of the first motor module 117-1 is supplied with a sinusoidal or cosinusoidal first operating current I1 to generate the test magnetic field 127.

FIG. 4A shows the case in which no further motor module 117 is arranged adjacent to the second end 163 of the first motor module 117-1. The test magnetic field 127 generated by the second edge drive coil 115-R of the first motor module 117-1 is therefore not subject to any interference based on an interference variable 128 of another motor module 117. The operating voltage U applied to the second edge drive coil 115-R thus comprises a correspondingly undisturbed sinusoidal or cosinusoidal waveform. If such a curve of the operating voltage U is detected in one of the motor modules 117 after all motor modules 117 have been energized simultaneously as an interference motor module 123, it may be concluded that the motor module 117-1 selected as the test motor module 121 comprises no immediately adjacent module at the second end 163.

The diagrams in FIGS. 4B to 4D show the case in which the second motor module 117-2 is arranged as an immediately adjacent motor module 125 in the direction of the second end 163 of the first motor module 117-1. By actuating the first edge drive coil 115-L of the second motor module 117-2 selected as the interference motor module 123 and the correspondingly generated interference variable 128, which interacts with the test magnetic field 127 of the first motor module 117-1, the test magnetic field 127 experiences a corresponding interference.

The interference may be detected in the first motor module 117-1 by a corresponding change in the operating voltage U dropping across the correspondingly actuated second edge drive coil 115-R. The correspondingly detected voltage change may comprise both the voltage amplitude A and the voltage phase q of the operating voltage U.

The voltage change of the operating voltage U may be detected in the first motor module 117-1 selected as the test motor module 121, for example, by a regulating unit 165 which is set up to control the establishment of the test magnetic field 127 by actuating the second edge drive coil 115-R.

In FIG. 4B, the first edge drive coil 115-L of the second motor module 117-2 is supplied with a sinusoidal or cosinusoidal second operating current I2. When the first edge drive coil 115—of the second motor module 117-2 is supplied with a sinusoidal or cosinusoidal second operating current I2, an interference variable 128 in the form of an interference magnetic field 129 is generated.

In the diagram if FIG. 4C, the first edge drive coil 115-L of the second motor module 117-2 is supplied with a zero current as the second operating current I2 in order to generate the interference variable 128. In order to supply the first edge drive coil 115-L with a zero current as the second operating current I2, a compensating current is required which counteracts a current induced by the test magnetic field 127 or a voltage induced by the test magnetic field 127 at the first edge drive coil 115-L of the interference motor module 123. This generates an interference variable 128 in the form of an interference magnetic field 129.

The different currents in FIGS. 4B and 4C may lead to different interference variables 128, which may cause different interferences to the test magnetic field 127.

In FIG. 4D, as an alternative to the active energization of the first edge drive coil 115-L of the second motor module 117-2 to generate the interference variable 128 in the form of an interference magnetic field 128, the first edge drive coil 115-L of the second motor module 117-2 is switched to a short-circuit state on the basis of control signals from the controller 109, wherein an interference variable 128 in the form of a short circuit 132 is generated. The active step carried out on the basis of control signals 109 from is thereby intended to short-circuit the first edge drive coil 115-L of the second motor module 117-2 and not to supply it with current, so that the short circuit 132 is the interference variable 128.

An interference magnetic field is also passively generated in the case of the interference variable in the form of a short circuit. Passive means that the interference magnetic field is not generated by actively energizing the first edge drive coil 115-L of the second motor module 117-2. Through interaction of the test magnetic field 127 of the first motor module 117-1 selected as the test motor module 121 with the short-circuited first edge drive coil 115-L of the second motor module 117-2 selected as the interference motor module 123, a voltage or current may be induced in the short-circuited first edge drive coil 115-L, through which the short-circuited first edge drive coil 115-L of the second motor module 117-2 generates a corresponding interference magnetic field 129. This allows the interference magnetic field 129 to be generated automatically by induction through interaction of the corresponding drive coil 115 with the test magnetic field 127, without the need for active energization of the respective drive coil 115 of the interference motor module 123 to generate the interference magnetic field.

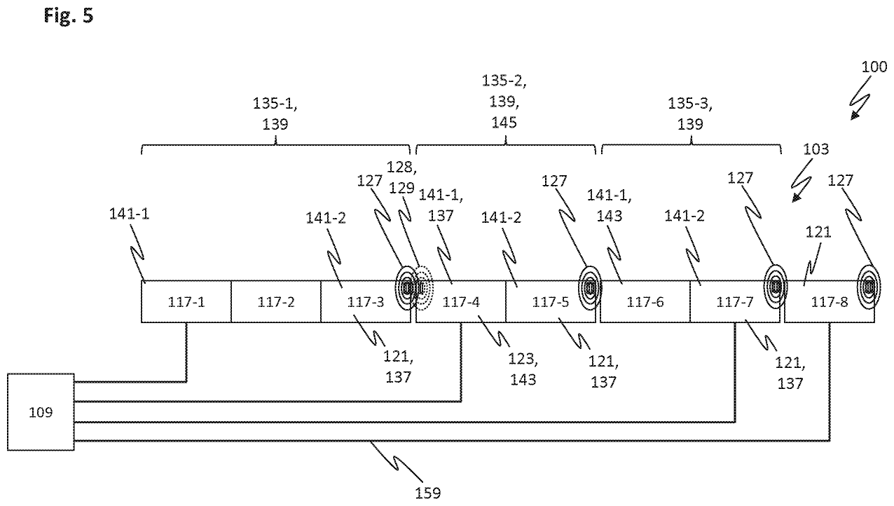

FIG. 5 shows a further schematic depiction of the linear transport system 100 according to a further embodiment. In the embodiment shown, the motor modules 117 of the stator 111 are grouped together in motor module strings 135. In a motor module string 135, at least two motor modules 117 are embodied and connected to one another by wires in accordance with the application. In the exemplary embodiment, eight motor modules 117, a first motor module 117-1, a second motor module 117-2, a third motor module 117-3, a fourth motor module 117-4, a fifth motor module 117-5, a sixth motor module 117-6, a seventh motor module 117-7, and an eighth motor module 117-8 are combined into a first motor module string 135-1, a second motor module string 135-2, and a third motor module string 135-3. The first to third motor modules 117-1, 117-3 are combined in the first motor module string 135-1. The fourth and fifth motor modules 117-4, 117-5 are combined in the second motor module string 135-2. The sixth and seventh motor modules 117-6, 117-7 are combined in the third motor module string 135-3. The eighth motor module 117-8 is shown as a separate motor module.

The first to third motor module strings 135-1, 135-2, 135-3 are connected to the controller 109 by corresponding data lines 159. Each motor module string 135-1, 135-2, 135-3 comprises a first edge motor module 141-1 and a second edge motor module 141-2. The first and second edge motor modules 141-1, 141-2 of two motor module strings 135 arranged immediately adjacent to each other along the guide rail 105 are arranged adjacent to each other. In order to be able to determine the individual positions of the various motor module strings 135 relative to each other, at least one motor module string 135 is selected as a test motor module string 139 and a further motor module string 135 is selected as an interference motor module string 145 in accordance with the method according to the application.

In the embodiment shown, all second edge motor modules 141-2 of the motor module strings 135 shown that are selected as test edge motor modules 137 are simultaneously actuated to generate the test magnetic fields 127. Analogously to the embodiments of FIGS. 2 and 3, the second edge drive coils 115-R arranged at the second ends 163 of the second edge motor modules 141-2 are energized for this purpose. All first edge motor modules 141-1 of the various motor module strings 135 are actuated sequentially as interference edge motor modules 143 to generate the interference magnetic fields 129.

Again, in accordance with the above embodiments, the first edge drive coils 115-L arranged at the first ends 161 of the first edge motor modules 141-1 are actuated for this purpose. FIG. 5 shows exclusively that the first edge motor module 141-1 of the second motor module string 135-2 is actuated to generate the respective interference magnetic field 129. The first edge motor modules 141-1 of the further motor module strings 135 may be actuated at other times to generate the respective interference magnetic fields 129.

According to the embodiment in FIG. 3, the second edge motor modules 141-2 selected as test edge motor modules 137 may be controlled simultaneously to generate the test magnetic fields 127, and the first edge motor modules 141-1 selected as interference edge motor modules 143 may be actuated sequentially to generate the interference magnetic fields 129.

Alternatively, the second edge motor modules 141-2 selected as test edge motor modules 137 may be controlled sequentially to generate the test magnetic fields 127, and the first edge motor modules 141-1 selected as interference edge motor modules 143 may be actuated simultaneously to generate the interference magnetic fields 129.

In a further embodiment, the second motor module string 135-2 is selected as the test motor module string 139. The first motor module string 135-1 and the third motor module string 135-3 are selected as corresponding interference motor module strings 145. In order to determine the motor module strings 135 arranged immediately adjacent to the second motor module string 135-2 selected as the test motor module string 139, the two edge motor modules 141-1, 141-2, i.e. the fourth motor module 117-4 and the fifth motor module 117-5 of the second motor module string 135-2, are selected and actuated as test edge motor modules 137 of the test motor module string 139 for generating corresponding test magnetic fields 127.

Furthermore, in the first motor module string 135-1, the third motor module 117-3 is selected and controlled as an interference edge motor module 143, and in the third motor module string 135-3, the sixth motor module 117-6 is selected and actuated as a further interference edge motor module 143 of the respective interference motor module strings 145 for generating the interference magnetic fields 129.

After generating the test magnetic fields 127 with the aid of the test edge motor modules 137 of the second motor module string 135-2 and after the corresponding interference magnetic fields 129 have been generated by the interference edge motor modules 143 of the first and third motor module strings 135-1 selected as interference motor module strings 145, 135-3, the first and third motor module strings 135-1, 135-3 may be identified as directly adjacent motor module strings 135 to the second motor module string 135-2 in accordance with the method steps described above when interferences in the test magnetic fields 127 are detected.

After selecting the respective test edge motor modules 137 or interference edge motor modules 143 of the respective test motor module strings 139 or interference motor module strings 145, the method proceeds analogously to the method steps described above. In the case of the motor modules 117 of the stator 111 being embodied in motor module strings 135, the only difference to the embodiment of FIG. 1 is that, in order to determine the complete topology of the linear transport system 100, only the edge motor modules 141-1, 141-2 of the respective motor module strings 135 are selected as test motor modules 121 or interference motor modules 123.

Since the motor modules 117 of a common motor module string 135 are connected to one another by wires, the individual positions of the motor modules 117 within the motor module strings 135 of the controller 109 are already known. Only the positioning of the individual motor module strings 135 on the stator 111, i.e. the relative positioning of the various motor module strings 135 with regard to one another, is unknown to the controller 109 at the time of carrying out the method according to the application. In order to determine the relative positioning of the individual motor module strings 135 in the stator 111 with respect to one another, only the edge motor modules 141-1, 141-2 of the various motor module strings 135 need to be taken into account in accordance with the method according to the application.

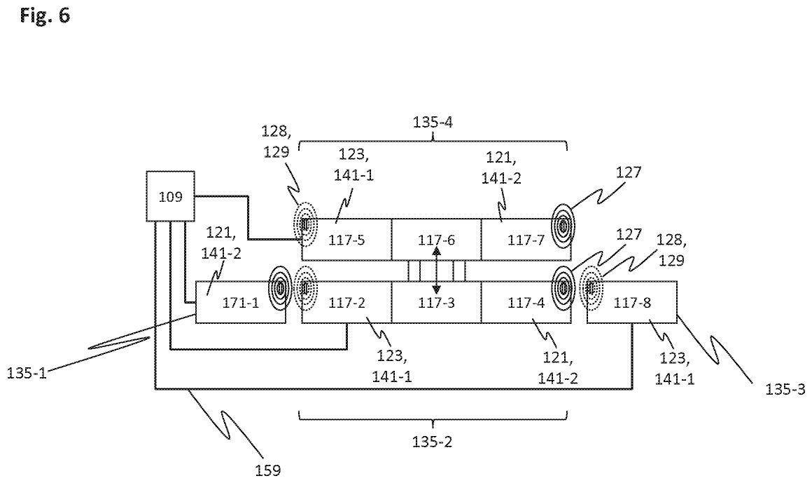

FIG. 6 shows a further schematic depiction of the linear transport system 100 according to a further embodiment. In the embodiment shown, the motor modules 117 of the stator 111 are grouped into four motor module strings 135. A first motor module string 135-1, a second motor module string 135-2, and a third motor module string 135-3 are arranged one behind the other along the longitudinal axis LA. A fourth motor module string 135-4 is shown in parallel to the second motor module string 135-2 and is combined with the second motor module string 135-2 in a switch module 167.

For the sake of clarity, only one motor module 117 of the first motor module string 135-1 and of the third motor module string 135-3 is shown. However, this should not have a limiting effect.

Depending on the position of the switch module 167, the first motor module string 135-1 may be connected to the second motor module string 135-2 or the fourth motor module string 135-4. Depending on the position of the switch module 167, a movable unit 101 may thus be moved from the first motor module string 135-1 along the second motor module string 135-2 or along the fourth motor module string 135-4.

By carrying out the method described in the embodiment of FIG. 5 by energizing the second edge motor modules 141-2 of all motor module strings 135 to generate the test magnetic fields 127 and by correspondingly energizing all first edge motor modules 141-1 to generate the corresponding interference magnetic fields 129, the respective adjacent first edge motor module 141-1 of the respective adjacent motor module string 135, if present, may be determined for each second edge motor module 141-2 of a motor module string 135.

In the present example, knowing that the second motor module string 135-2 and the fourth motor module string 135-4 are arranged in the switch module 167, the position of the switch module 167 may be determined.

In the present example, by carrying out the aforementioned method, it is determined that the first motor module 117-1, which is part of the first motor module string 135-1, and the second motor module 117-2, which is part of the second motor module string 135-2, are arranged immediately adjacent to each other. Accordingly, it is determined that the first motor module string 135-1 and the second motor module string 135-2 are arranged immediately adjacent to each other. Based on this, the respective position of the switch module 167 may be determined.

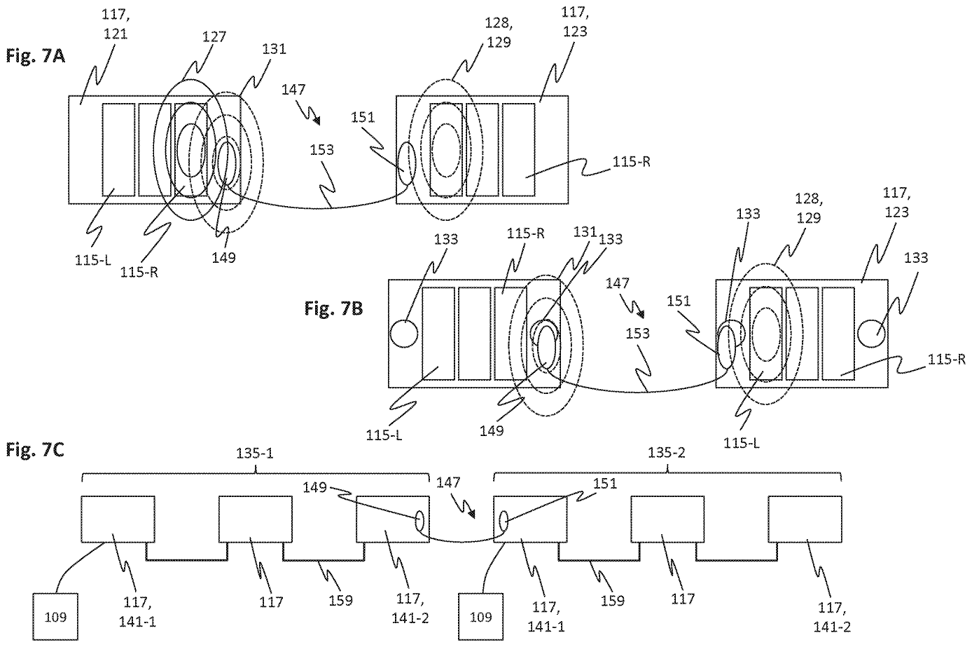

FIGS. 7A to 7C show further schematic depictions of the linear transport system 100 according to a further embodiment. In the embodiments shown, the linear transport system 100 further comprises a signal transmitting device 147 with a first transmitting element 149 and a second transmitting element 151, which are connected to each other via a connecting line 153.

FIG. 7A shows two motor modules 117 according to the embodiments described above comprising drive coils 115. The motor modules 117 are separated from each other by a gap 155. The signal transmitting device 147 is arranged with the first transmitting element 149 on the first motor module 117-1 and with the second transmitting element 151 on the second motor module 117-2. Via the two transmitting elements 149, 151, a magnetic interference signal 131 caused by the interference variable 128 of the second motor module 117-2 selected as the interference motor module 123 may be transmitted into the effective range of the test magnetic field 127 of the first motor module 117-1 selected as the test motor module 121.

Due to the gap 155 between the two motor modules 117, the effect of the interference variable 128 on the test magnetic field 127 may be too small for an interference caused by the interference variable 128 in the test magnetic field 127 to be detectable or to reach or exceed the predefined limit value.

However, by transmitting the magnetic interference signal 131 of the interference variable 128 into the effective range of the test magnetic field 127 via the signal transmitting device 147, an interference of the test magnetic field 127 caused by the interference variable 128 may nevertheless be registered and the second motor module 117-2, which is immediately adjacent to the first motor module 117-1, may still be identified.

According to an embodiment, the first and second transmitting elements 149, 151 are embodied as transmitting coils. In the transmitting coil of the second transmitting element 151, which is arranged in the effective range of the interference variable 128, a corresponding induced voltage or induced current may be generated with the aid of induction through the interference variable 128. In the transmitting coil of the first transmitting element 149 connected to the transmitting coil of the second transmitting element 151, a corresponding voltage or current may be induced by the voltage or current induced in the transmitting coil of the second transmitting element 151. This allows for generating a magnetic field with the aid of the transmitting coil of the first transmitting element 149, wherein the magnetic interference signal 131 may be introduced into the effective range of the test magnetic field 127 by the transmitting coil of the first transmitting element 149.

According to a further embodiment, at least the second transmitting element 151 arranged in the effective range of the interference variable 128 may be embodied as a magnetic sensor element. The interference variable 128 generated by the interference motor module 123 is detected via the second transmitting element 151 embodied as a magnetic sensor element. The electrical measurement signals triggered by the interference variable 128 in the second transmitting element 151 embodied as a magnetic sensor element are forwarded by the signal transmitting device 143 to the transmitting coil of the first transmitting element 149, wherein the transmitting coil of the first transmitting element 149 generates the magnetic interference signal 131.

FIG. 7B shows a further example of determining immediately adjacent motor modules 125. In the example shown, no test magnetic field 127 is generated. Instead, a corresponding interference variable 128 is generated only by supplying current to at least one drive coil 115 of the motor module 117 selected as the interference motor module 123.

In the example shown, the motor modules 117 spaced apart from one another are each embodied with magnetic sensor elements 133.

The signal transmitting device 143 is further embodied in accordance with the embodiment shown in FIG. 7A. The second transmitting element 151 is arranged in the effective range of the interference variable 128 and embodied to detect the interference variable 128. The second transmitting element 151 may also be embodied as a transmitting coil or as a Hall sensor. The first transmitting element 149 is arranged in an effective range of a magnetic field sensor 133 of the motor module 1117 selected as the test motor module 121 and is embodied to generate a magnetic interference signal 131 and introduce it into the effective range of the magnetic sensor element 133. The first transmitting element 149 may be embodied as a transmitting coil for this purpose.

By transmitting the magnetic interference signal 131 into the effective range of the magnetic sensor element 133 via the first transmitting element 149 of the signal transmitting device 143, the magnetic interference signal 131 may be detected via the magnetic sensor element 133 of the motor module 117 selected as the test motor module 121.

In this case, the presence of a motor module 125 immediately adjacent to the test motor module 121 is not detected due to interference generated by the interference variable 128 of the motor module 117 selected as the interference motor module 123 in the test magnetic field 127 of the motor module 117 selected as the test motor module 121. Instead, a motor module 125 immediately adjacent to the test motor module 121 is registered if the interference signal 131 introduced into the effective range of the magnetic sensor element 133 by the first transmitting element 149 is detected by at least one magnetic field sensor 133 of the motor module 117 selected as the test motor module 121.

The identification of the motor module 117 selected as the interference motor module 123, which is located directly adjacent to the test motor module 121, is carried out analogously to the method steps described above, in that the generation of the interference variables 128 by the various motor modules 117 selected as interference motor modules 123 is carried out sequentially in time.

In FIG. 7C, according to the embodiment shown in FIG. 5, motor modules 117 are combined into two motor module strings 135. The signal transmitting device 147 is positioned between two edge motor modules 141-1, 141-2 of the motor module strings 135-1, 135-2 arranged next to each other. The mode of operation of the signal transmitting device 147 in the embodiment shown is analogous to the mode of operation of the embodiment in FIG. 7A.

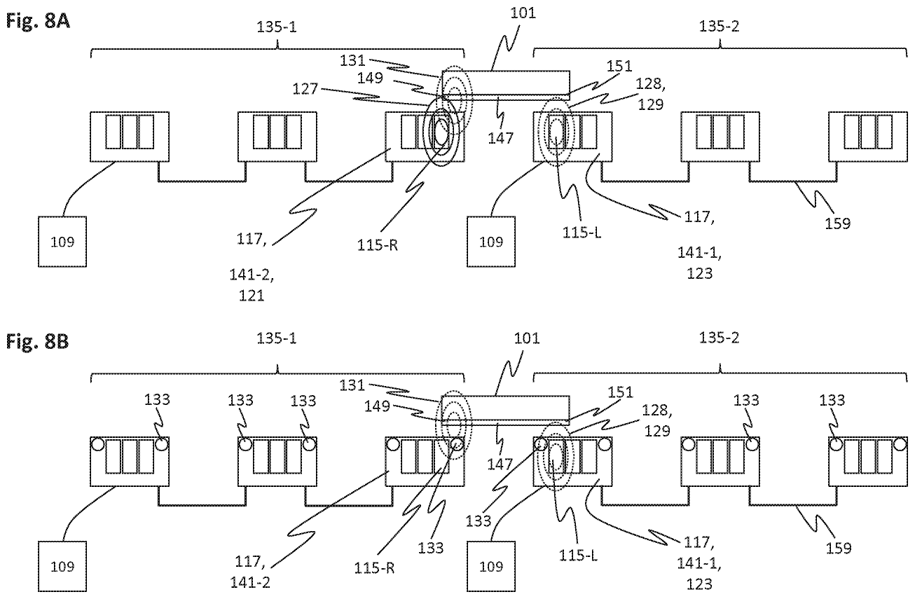

FIGS. 8A and 8B show further schematic depictions of the linear transport system 100 according to a further embodiment.

In the embodiments shown, the signal transmitting device 147 is positioned on a movable unit 101 of the linear transport system 100. By moving the movable unit 101 along the guide rail 105 to the desired motor modules 117 of the stationary unit 103, the first and second transmitting elements 149, 151 of the signal transmitting device 147 may be positioned in the effective range of the test magnetic field 127 of a motor module 117 selected as a test motor module 121 and in the effective range of the interference variable 128 of a motor module 117 selected as an interference motor module 123, respectively.

The signal transmitting device 147 may thus be moved by the movable unit 101 to the respective motor modules 107 to be examined. The mode of operation of the signal transmitting device 147 is described with reference to the positioning of the movable unit 101 in a transmitting position, in which the first transmitting element 149 is positioned in the effective range of the test magnetic field 127 of the test motor module 121 and the second transmitting element 151 is positioned in the effective range of the interference variable 128 of the interference motor module 123, according to the embodiments shown in FIGS. 7A to 7C.

The first and/or second transmitting elements 151 may be embodied as transmitting coils. The transmitting coils may, for example, be embodied as conductor paths in printed circuit boards of the rotor 113 of the movable unit 101. For example, the transmitting coils of the first and second transmitting elements 149, 151 may each be arranged around drive magnet elements 119 of the rotor 113.

The example shown in FIG. 8B represents the analogous case to FIG. 7B. In the example shown, the motor modules 117 comprise magnetic sensor elements 133. The second transmitting element 151 is arranged in the effective range of the interference variable 128 of the interference motor module 123, and the first transmitting element 149 is arranged in the effective range of at least one magnetic sensor element 133 of the test motor module 121.

The motor module 125 immediately adjacent to the test motor module 121 is registered in accordance with the example in FIG. 7B by the interference variable 128 of the interference motor module 123 being detected by the second transmitting element 151, a corresponding magnetic interference signal 131 is introduced into the effective range of at least one magnetic sensor element 133 of the test motor module 121 by the first transmitting element 149 and detected by the respective magnetic sensor element 133.

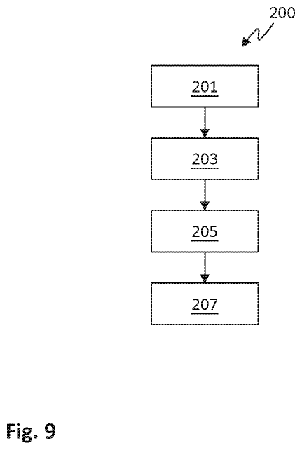

FIG. 9 shows a flowchart of the method 200 for operating a linear transport system 100 according to an embodiment. In order to operate a linear transport system 100, in a test magnetic field generating step 201, control signals are first output from the controller 109 to at least one drive coil 115 of a test motor module 121 to generate a test magnetic field 127.

In an interference generating step 203, control signals are output from the controller 109 to at least one drive coil 115 of at least one interference motor module 123 to generate an interference 128.

In an interference detecting step 205, the controller 109 detects an interference of the test magnetic field 127 caused by the interference variable 128.

In an arrangement detecting step 207, the controller 109 detects a motor module 125 immediately adjacent to the test motor module 121 if the detected interference of the test magnetic field caused by the detected interference variable 128 reaches or exceeds a predefined limit value.

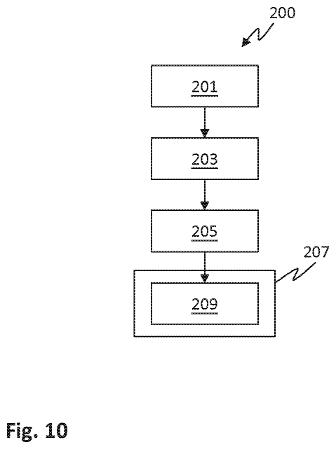

FIG. 10 shows a further flowchart of the method 200 for operating a linear transport system 100 according to a further embodiment. The embodiment of FIG. 10 is based on the embodiment of FIG. 9 and comprises all the method steps described therein.

In the embodiment shown, the arrangement determining step 207 comprises an identifying step 209. In the identifying step 209, the at least one interference motor module 123 is identified as the motor module 125 immediately adjacent to the test motor module 121. The identification is based on a temporal sequence of the generation of the interference variable 128 and the determination of the interference of the test magnetic field 127.

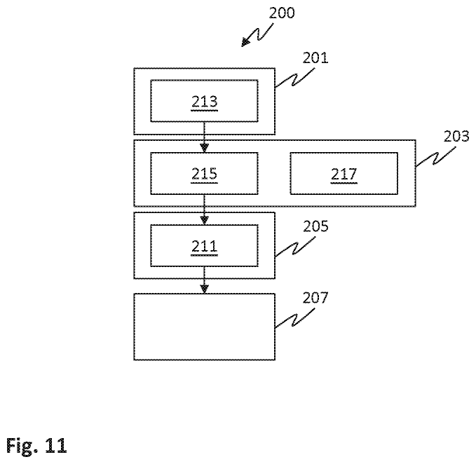

FIG. 11 shows a further flowchart of the method 200 for operating a linear transport system 100 according to a further embodiment. The embodiment of FIG. 11 is based on the embodiment in FIG. 9 and comprises all the method steps described therein.

In the embodiment shown, the test field magnetic field generating step 201 comprises the controller 109 outputting control signals to the drive coil 115 of the test motor module 121 to energize the drive coil 115 of the test motor module 121 with a first operating current I1 in a first energizing step 213.

The interference generating step 203 comprises the controller 109 outputting control signals to the drive coil 115 of the at least one interference motor module 123 in order to energize the drive coil 115 of the interference motor module 123 with a second operating current I2 in a second energizing step 215.

Alternatively, control signals are output by the controller 109 to the drive coil 115 and the drive coil 115 of the interference motor module 123 is switched to a short-circuit state in a switching step 217. In this case, the interference variable 128 is provided by the short-circuit state into which the drive coil 115 of the motor module 117 selected as the interference motor module 123 is switched by the control signals. In the short-circuited drive coil 115, an induced voltage or an induced current is generated by interacting with the test magnetic field 127, on the basis of which a corresponding interference magnetic field 129 is generated by the drive coil 115.

In the embodiment shown, the interference of the test magnetic field 127 is determined in the interference determining step 205 by the controller 109 determining a voltage change of an operating voltage U of the drive coil 115 of the test motor module 121 generating the test magnetic field 127 in a voltage change determining step 211. The predefined limit value for determining the interference of the test magnetic field 127 is defined here by a minimum voltage change.

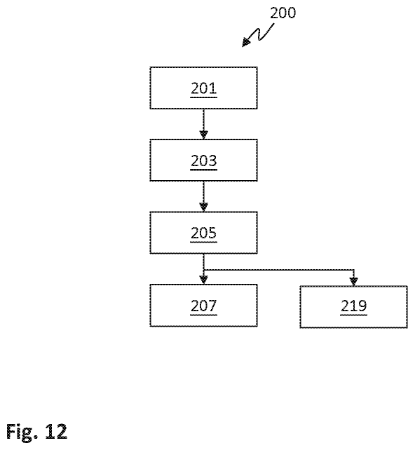

FIG. 12 shows a further flowchart of the method 200 for operating a linear transport system 100 according to a further embodiment. The embodiment in FIG. 12 is based on the embodiment in FIG. 9 and comprises all the method steps described therein.

In the embodiment shown, a further arrangement determining step 219 determines that there is no motor module 125 immediately adjacent to the test motor module 121, if no interference of the test magnetic field 127 is determined for any of the generated interference variables 128 of the motor modules 117 selected as interference motor modules 123.

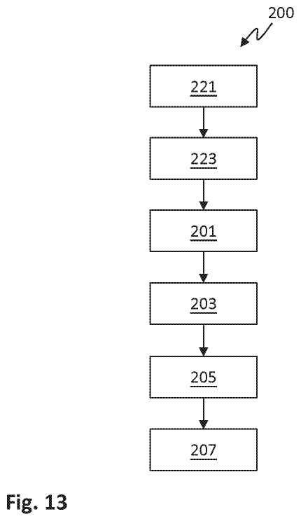

FIG. 13 shows a further flowchart of the method 200 for operating a linear transport system 100 according to a further embodiment. The embodiment in FIG. 13 is based on the embodiment in FIG. 9 and comprises all the method steps described therein.

The embodiment shown describes the case in which the motor modules 117 are grouped into corresponding motor module strings 135. In a motor module determining step 221, a test edge motor module 137 of a test motor module string 139 and an interference edge motor module 143 of an interference motor module string 145 are determined by the controller 109.

In a motor module selecting step 223, the test edge motor module 137 of the test motor module string 139 is selected as the test motor module 121 for generating the test magnetic field 127, and the interference edge motor module 143 of the interference motor module string 145 is selected as the interference motor module 123 for generating the interference magnetic field 129.size 128.

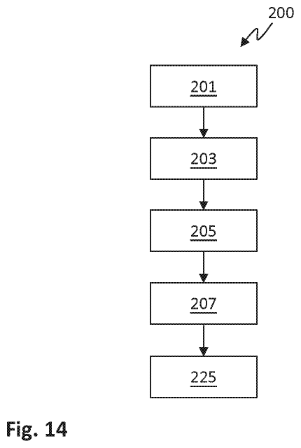

FIG. 14 shows a further flowchart of the method 200 for operating a linear transport system 100 according to a further embodiment. The embodiment in FIG. 14 is based on the embodiment in FIG. 9 and comprises all the method steps described therein.

In the embodiment shown, in a topology determining step 225, the controller 109 determines a topology of the motor modules 117 of the stationary unit 103 by determining at least one immediately adjacent motor module 125 for the motor modules 117 of the plurality of motor modules 117 of the stationary unit 103.

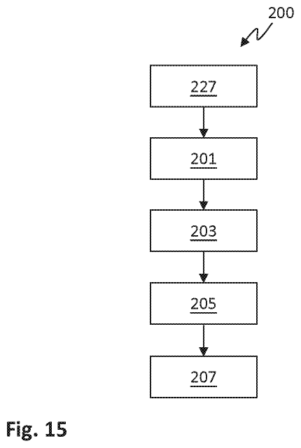

FIG. 15 shows a further flowchart of the method 200 for operating a linear transport system 100 according to a further embodiment. The embodiment shown in FIG. 15 is based on the embodiment shown in FIG. 9 and comprises all the method steps described therein.

In the embodiment shown, the linear transport system 100 comprises the signal transmitting device 147 embodied at least one movable unit 101. In a positioning step 227, control signals are output from the controller 109 to drive coils 115 of the motor modules 117 for positioning the movable unit 101 in a transmitting position. In the transmission position of the movable unit 101, the first and second transmitting elements 149, 151 of the signal transmitting device 147 are positioned in an effective range of the test magnetic field 127 of the test motor module 121 and the effective range of the interference variable 128 of the interference motor module 123. The signal transmitting device 147 may thus use the first and second transmitting elements 149, 151 in order to bring a magnetic interference signal generated by the interference variable 128 into the effective range of the test magnetic field 127.

The embodiments of method 200 of FIGS. 9 to 15 may be combined in any desired way.

This invention has been described with respect to exemplary embodiments. It is understood that changes can be made and equivalents can be substituted to adapt these disclosures to different materials and situations, while remaining with the scope of the invention. The invention is thus not limited to the particular examples that are disclosed, but encompasses all the embodiments that fall within the scope of the claims.

TABLE 1
List of reference symbols: 1-167

100 linear transport system
101 movable unit
103 stationary unit
105 guide rail
107 linear motor
109 controller
111 stator
113 rotor
114 stator tooth
115 drive coil
115-L first edge drive coil
115-R second edge drive coil
117 motor module
117-1 first motor module
117-2 second motor module
117-3 third motor module
117-4 fourth motor module
117-5 fifth motor module
117-6 sixth motor module
117-7 seventh motor module
117-8 eighth motor module
119 drive magnet element
121 test motor module
123 interference motor module
125 immediately adjacent motor module
127 test magnetic field
128 interference variable
129 interference magnetic field
131 magnetic interference signal
132 short circuit
133 magnetic sensor element
135 motor module string
135-1 first motor module string
135-2 second motor module string
135-3 third motor module string
135-4 fourth motor module string
137 test edge motor module
139 test motor module string
141 first edge motor module
141-2 second edge motor module
143 interference edge motor module
145 interference motor module string
147 signal transmitting device
149 first transmitting element
151 second transmitting element
153 connecting line
155 gap
159 data line
161 first end
163 second end
165 controller
167 switch module

TABLE 2
List of reference symbols: 200-

200 method
201 test magnetic field generating step
203 interference generating step
205 interference detecting step
207 arrangement determining step
209 identifying step
211 voltage change determining step
213 first energizing step
215 second energizing step
217 switching step
219 further arrangement determining step
221 motor module determining step
223 motor module selecting step
225 topology determining step
227 positioning step
U operating voltage
A voltage amplitude
φ voltage phase
I1 first operating current
I2 second operating current
t time

1. A computer-implemented method for operating a linear transport system having:
a controller, and
a stationary unit having a guide rail for guiding a movable unit and a plurality of motor modules arranged along the guide rail,
wherein the motor modules each comprise drive coils for providing a drive magnetic field for driving the movable unit along the guide rail; and
wherein the method comprises:
outputting control signals from the controller to at least one drive coil of at least one motor module selected as a test motor module from the plurality of motor modules to generate a test magnetic field of the test motor module in a test magnetic field generating step;
outputting control signals by the controller to at least one drive coil of at least one motor module selected as an interference motor module from the plurality of motor modules for generating an interference variable of the at least one interference motor module in an interference variable generating step;
determining an interference of the test magnetic field of the motor module selected as the test motor module caused by the interference variable of the motor module selected as the interference motor module by the controller in an interference determining step; and
determining an immediately adjacent interference motor module selected as the test motor module by the controller in an arrangement determining step if the detected interference of the test magnetic field by the interference variable reaches or exceeds a predefined limit value.

2. The method according to claim 1, wherein the arrangement determining step comprises:
identifying the at least one interference motor module as the motor module immediately adjacent to the test motor module based on a temporal sequence of the generation of the interference variable by the at least one interference motor module and the determination of the interference of the test magnetic field with the aid of the controller in an identifying step.

3. The method according to claim 1, wherein the interference determining step comprises:
determining a voltage change of an operating voltage of the drive coil of the test motor module generating the test magnetic field with the aid of the controller in a voltage change determining step,
wherein the predefined limit value is defined by the voltage change.

4. The method according to claim 3, wherein the voltage change comprises a change in a voltage amplitude and/or a change in a voltage phase of the operating voltage.

5. The method according to claim 1, wherein the test magnetic field generating step comprises:
outputting control signals with the aid of the controller to the drive coil of the test motor module for energizing the drive coil of the test motor module with a first operating current in a first energizing step.

6. The method according to claim 1, wherein the interference generating step comprises:
outputting control signals by the controller to the drive coil of the at least one interference motor module for energizing the drive coil of the at least one interference motor module with a second operating current and for generating an interference magnetic field in a second energizing step,
wherein the interference variable is given by the interference magnetic field.

7. The method according to claim 1, wherein the interference variable generating step comprises:
outputting control signals by the controller to the drive coil of the at least one interference motor module for generating the interference variable by switching the drive coil of the at least one interference motor module into a short-circuit state in a switching step,
wherein the interference variable is provided by a short circuit in the drive coil of the motor module selected as the interference motor module.

8. The method according to claim 5, wherein the first operating current of the drive coil of the test motor module comprises a waveform selected from the following list: sinusoidal waveform, cosine waveform, sawtooth waveform, triangular waveform, square waveform.

9. The method according to claim 6, wherein the second operating current of the drive coil of the at least one interference motor module comprises a waveform selected from the following list: sinusoidal waveform, cosine waveform, sawtooth waveform, triangular waveform, square waveform, or zero current.

10. The method according to claim 1, wherein:
for a plurality of motor modules selected as interference motor modules, a plurality of interference variables are generated by actuating the respective drive coils of the motor modules selected as interference motor modules, and
wherein the plurality of interference variables are checked to determine whether interferences of the test magnetic field of the test motor module are detected.

11. The method according to claim 10, wherein the generation of the plurality of interference variables of the plurality of interference motor modules is carried out sequentially in time.

12. The method according to claim 1, wherein for a plurality of motor modules selected as test motor modules, a plurality of test magnetic fields is generated by actuating the respective drive coils of the motor modules selected as test motor modules.

13. The method according to claim 12, wherein:
generating the plurality of test magnetic fields of the plurality of motor modules selected as test motor modules is carried out simultaneously and generating the plurality of interference variables of the plurality of motor modules selected as interference motor modules is carried out sequentially over time, or
wherein generating the plurality of test magnetic fields of the plurality of motor modules selected as test motor modules is carried out sequentially in time and generating the plurality of interference variables of the plurality of motor modules selected as interference motor modules is carried out simultaneously.

14. The method according to claim 1, further comprising:
determining that there is no immediately adjacent motor module to the test motor module if no interference of the test magnetic field is determined for any of the generated interference variables of the motor modules selected as interference motor modules in a further arrangement determining step.

15. The method according to claim 1, wherein:
the motor modules of the plurality of motor modules of the stationary unit are combined into motor module strings,
wherein each motor module string comprises at least two motor modules connected to each other by wires connected to each other in a wired manner; and
wherein the method further comprises:
determining a test edge motor module of a test motor module string and an interference edge motor module of an interference motor module string with the aid of the controller in a motor module determining step,
wherein the test edge motor module is wire-connected to only one further motor module of the test motor module string, and wherein the interference edge motor module is wire-connected to only one other motor module of the interference motor module string; and
selecting the test edge motor module of the test motor module string as the test motor module for generating the test magnetic field and selecting the interference edge motor module of the interference motor module string as the interference motor module for generating the interference variable with the aid of the controller in a motor module selecting step.

16. The method according to claim 1, wherein the method further comprises:
determining a topology of the motor modules of the stationary unit by determining at least one immediately adjacent motor module for the motor modules of the plurality of motor modules of the stationary unit with the aid of the controller in a topology determining step.

17. The method according to claim 1, wherein the method is carried out when starting up the linear transport system and/or after adding and/or removing a motor module to/from the plurality of motor modules.

18. A linear transport system having a controller configured to carry a the method for operating the linear transport system according to claim 1, wherein:
the stationary unit comprises the guide rail for guiding the movable unit and the plurality of motor modules arranged along the guide rail,
wherein the motor modules each comprise said drive coils for providing the drive magnetic field for driving the movable unit along the guide rail, and
wherein the drive coils are arranged to generate the test magnetic field and/or the interference variable.
